(19) United States
(12) Patent Application Publication
(10) Pub. No.: US 2026/0144066 A1
(43) Pub. Date: May 21, 2026

(54) PACKAGE STRUCTURE AND METHOD FOR FABRICATING THE SAME

(71) Applicant: Taiwan Semiconductor Manufacturing Company, Ltd., Hsinchu (TW)

(72) Inventors: Shih-Wei LIU, Chiayi City (TW); Sing-Da JIANG, Taichung City (TW); Tsun-Yen WU, Hsinchu County (TW); Kathy Wei YAN, Hsinchu (TW)

(21) Appl. No.: 18/950,607

(22) Filed: Nov. 18, 2024

(51) Int. Cl. H01L 23/427; H01L 21/50

(52) U.S. Cl. CPC H10W 40/73; H10W 95/00

(57) ABSTRACT

A package structure is provided. The package structure includes a support structure including a first surface and a second surface opposite to the first surface. The package structure includes a device structure on the first surface of the support structure. The package structure includes a vapor chamber disposed in the support structure and over at least a portion of the device structure. The package structure includes a plurality of micro pillars formed on the second surface of the support structure and over the vapor chamber. The package structure also includes a liquid cooling component bonded over the second surface of the support structure and configured to circulate cooling liquid in contact with the micro pillars.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductive layers of material over a semiconductor substrate, and patterning the various material layers using lithography to form circuit components and elements thereon. Many integrated circuits are typically manufactured on a single semiconductor wafer, and individual dies on the wafer are singulated by sawing between the integrated circuits along a scribe line. The individual dies are typically packaged separately, in multi-chip modules, for example, or in other types of packaging.

Although existing methods of fabricating semiconductor structures have generally been adequate for their intended purposes, they have not been entirely satisfactory in all respects.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIGS. 1A through 1G illustrates cross-sectional views of intermediate steps during a process for fabricating a package structure in accordance with some embodiments.

FIG. 2 illustrates a plan view of the region P shown in FIG. 1G in accordance with some embodiments.

FIG. 3 illustrates a perspective view of the region P shown in FIG. 1G in accordance with some embodiments.

FIG. 4 illustrates a plan view of the region P shown in FIG. 1G in accordance with some embodiments.

FIG. 5 illustrates a plan view of the region P shown in FIG. 1G in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numbers are used to designate like elements. It should be understood that additional operations can be provided before, during, and after the method, and some of the operations described can be replaced or eliminated for other embodiments of the method.

Embodiments of package structures and methods for fabricating the same are provided. The package structure includes a plurality of vapor chamber sealed with vaporizable working fluid. The evaporation and condensation of the working fluid in the vapor chamber would help to dissipate the heat upward to the liquid cooling component. In addition, the package structure includes a plurality of micro pillars over the supporting structure so as to increase the surface area of the supporting structure, thereby improving the thermal dissipation of the overall package structure. In particular, the cooling liquid flows into the channel formed by the liquid cooling component, the waterproof sealant, and the micro pillars to dissipate the heat generated by the device dies of the package structure.

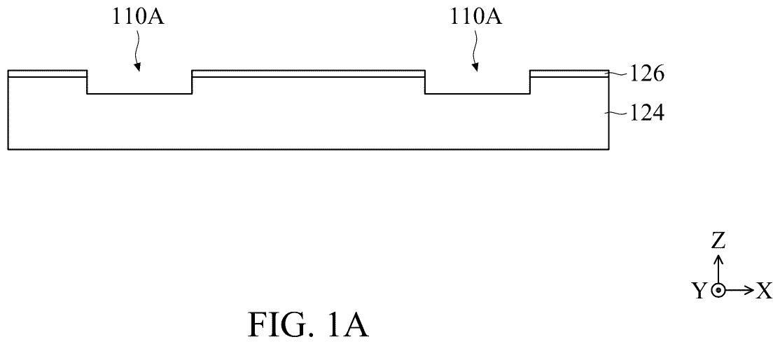

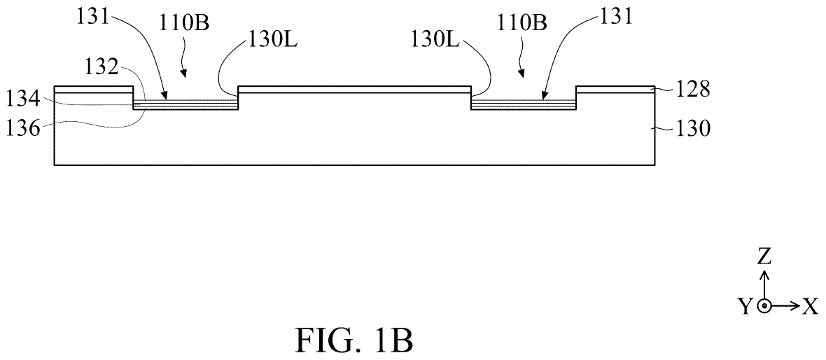

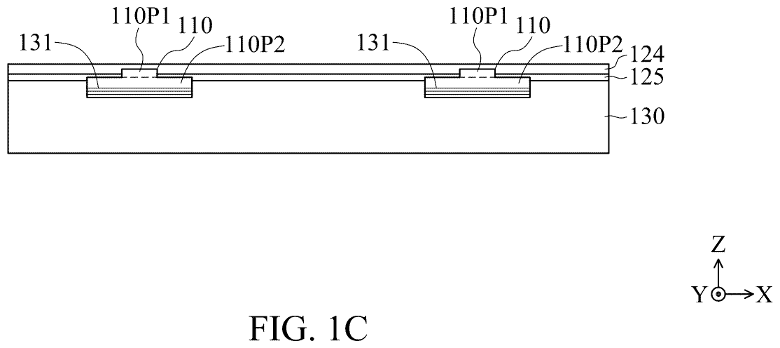

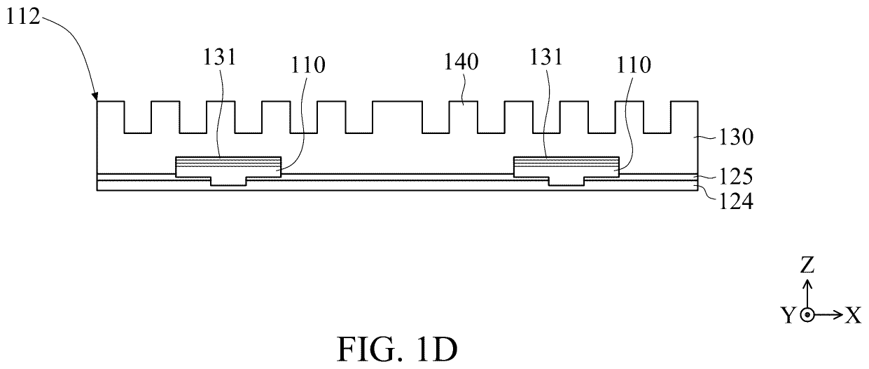

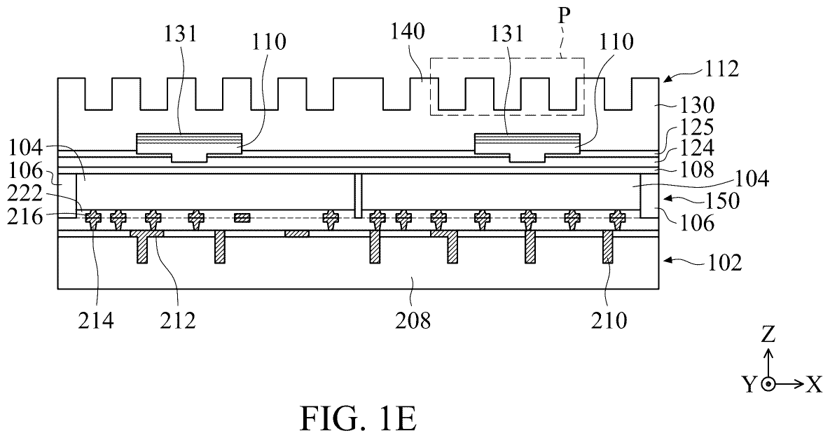

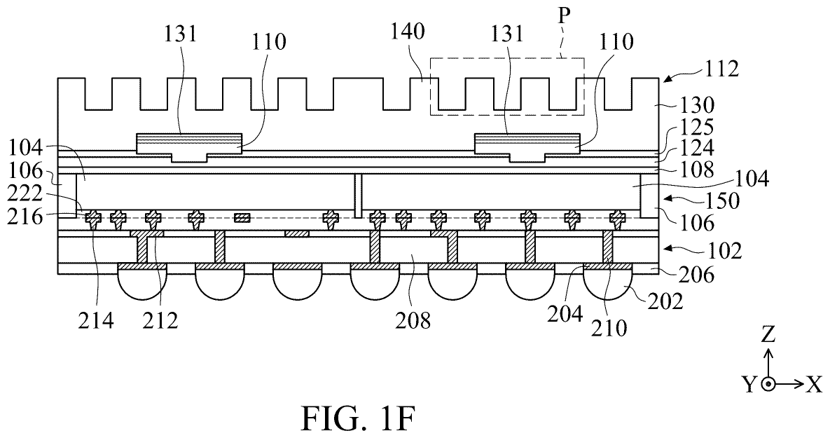

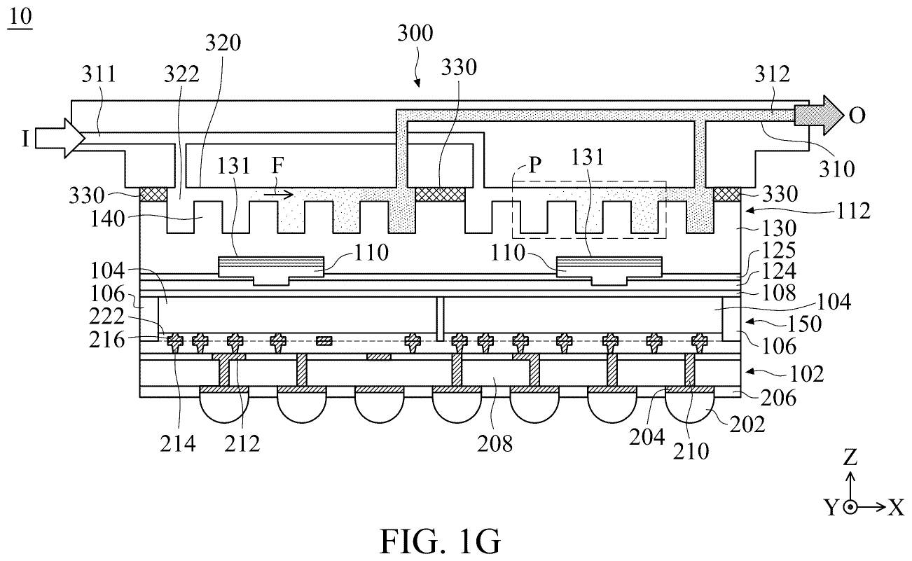

FIGS. 1A through 1G illustrates cross-sectional views of intermediate steps during a process for fabricating a package structure 10 in accordance with some embodiments. A shown in FIG. 1A, a first dielectric layer 126 is formed on a first substrate 124. In some embodiments, the first dielectric layer 126 may be formed on the first substrate 124 by a chemical vapor deposition (CVD) process, a physical vapor deposition (PVD) process, an atomic layer deposition (ALD) process, a thermal oxidation process, or some other suitable deposition or growth process. The first substrate 124 may, for example, be or include silicon, epitaxial silicon, germanium, silicon germanium, or some other suitable substrate material. The first dielectric layer 126 may, for example, be or include an oxide such as silicon dioxide or some other suitable material.

In some embodiments, a patterning process is performed on the first dielectric layer 126 and the first substrate 124 to form a plurality of first openings 110A in the first substrate 124. In some embodiments, the patterning process includes: forming a masking layer (not shown) on the first dielectric layer 126; performing an etching process (e.g., a dry etch process) on the first substrate 124 and the first dielectric layer 126 using the masking layer; and removing the masking layer from over the first dielectric layer 126. In other embodiments, a process for forming the first openings 110A includes: patterning the first substrate 124 to form the first openings 110A in the first substrate 124; depositing (e.g., by CVD, PVD, ALD, thermal oxidation, etc.) the first dielectric layer 126 on the first substrate 124; and performing an etch process (e.g., a dry etch process, a wet etch process, etc.) to remove portions of the first dielectric layer 126 from over a lower surface of the first substrate 124 that defines bottoms of the first openings 110A. In various embodiments, a thermal dispersion enhancement structure (for example, referring to 131 of FIG. 1B) is formed along one or more surfaces of the first substrate 124 that defines the first openings 110A.

As shown in FIG. 1B, a patterning process is performed on a second substrate 130 to form a plurality of second openings 110B in the second substrate 130. In some embodiments, the patterning process includes: forming a masking layer (not shown) on the second substrate 130; performing an etching process (e.g., a dry etch process) on the second substrate 130; and removing the masking layer from over the second substrate 130 (not shown). The second substrate 130 may, for example, be or include silicon, epitaxial silicon, germanium, silicon germanium, or some other suitable substrate material. In addition, a second dielectric layer 128 is formed on the second substrate 130 and a thermal dispersion enhancement structure 131 is formed on the lower surface of the second substrate 130 and in contact with lateral surfaces 130L of the second substrate 130 that define at least a portion of each of the second openings 110B. In some embodiments, the second dielectric layer 128 may be formed on the second substrate 130 by a CVD process, a PVD process, an ALD process, a thermal oxidation process, or some other suitable deposition or growth process. In various embodiments, the thermal dispersion enhancement structure 131 includes a dielectric layer 136, a seed layer 134 on the dielectric layer 136, and a thermal dispersion enhancement layer 132 on the seed layer 134. The dielectric layer 136 may be formed on the lower surface of the second substrate 130 and in contact with the lateral surfaces 130L of the second substrate 130 by, for example, a CVD process, a PVD process, an ALD process, a thermal oxidation process, or some other suitable deposition or growth process. The seed layer 134 may be formed on the dielectric layer 136 by, for example, a CVD process, a PVD process, or some other suitable growth or deposition process. The thermal dispersion enhancement layer 132 may by formed on the seed layer 134 by, for example, a CVD process, a PVD process, an electroplating process, an electroless plating process, or some other suitable growth or deposition process. In various embodiments, the thermal dispersion enhancement layer 132 has a grid structure or a mesh structure when viewed in top view.

In yet further embodiments, the second dielectric layer 128 may be formed on the second substrate 130 before the patterning process of FIG. 1B. In such embodiments, the second dielectric layer 128 is etched during the patterning process of FIG. 1B. The second dielectric layer 128 may, for example, be or include silicon dioxide or some other suitable dielectric material. The seed layer 134 may, for example, be or include titanium, tantalum, a nitride (e.g., titanium nitride, tantalum nitride, etc.), copper, or the like. The thermal dispersion enhancement layer 132 may, for example, be or include copper or some other suitable material.

Then, as shown in FIG. 1C, a vapor chamber bonding process is performed to bond the first substrate 124 to the second substrate 130 and form or define a plurality of vapor chambers 110. In particular, the first dielectric layer 126 and the second dielectric layer 128 are bonded as a dielectric layer 125. In some embodiments, the vapor chambers 110 are defined by a combination of the first openings 110A and the second openings 110B. The vapor chambers 110 each include a first portion 110P1 and a second portion 110P2. In some embodiments, a width of the first portion 110P1 is less than a width of the second portion 110P2. In various embodiments, the vapor chamber bonding process includes performing a vapor chamber charging process to form or deposit a vaporizable working fluid or working vapor in the first and/or second openings (110A of FIG. 1A and/or 110B of FIG. 1B) and a bonding process to bond the first substrate 124 to the second substrate 130 and seal the vapor chambers 110. By performing the vapor chamber charging process before the bonding process, the plurality of vapor chambers 110 may be sealed with the vaporizable working fluid or working vapor. In some embodiments, the bonding process includes performing a fusion bonding process or some other suitable bonding process. In various embodiments, the first openings (e.g., 110A of FIG. 1A) formed in the first substrate 124 (e.g., as illustrated and/or described in FIG. 1A) correspond to the first portions 110P1 of the vapor chambers 110 and the second openings (e.g., 110B of FIG. 1B) formed in the second substrate 130 (e.g., as illustrated and/or described in FIG. 1B) correspond to the second portions 110P2 of the vapor chambers 110.

In some embodiments, the vapor chamber charging process includes disposing the vaporizable working fluid in the first and/or second openings (110A of FIG. 1A and/or 110B of FIG. 1B) by an injection filling process, a vacuum filling process, some other suitable process, or any combination thereof. In various embodiments, the vaporizable working fluid may, for example, be or include a chlorofluorocarbon, a hydrochlorofluorocarbon, water, alcohol, silicon oil, liquid nitrogen, fluorine-containing fluid, acetone, methanol, ethanol, heptane, ammonia, some other suitable cooling liquid, or any combination thereof. In various embodiments, the vaporizable working fluid is disposed in at least the first portion 110P1 of each of the vapor chambers 110. The vaporizable working fluid is configured to facilitate spreading heat in the vertical direction from the first portion 110P1 of the vapor chambers 110 towards the second portion 110P2 of the vapor chambers 110. For example, during operation of the package structure, the generated heat is directed towards the vaporizable working fluid in the vapor chambers 110 that can induce evaporation of the vaporizable working fluid into a vapor. The evaporation of the vaporizable working fluid into the vapor efficiently transfers the heat in the vertical direction towards the liquid cooling component 300 (referring to FIG. 1G, for example). Further, the vapor may undergo a condensation process in the second portion 110P2 as heat is transferred towards the liquid cooling component 300, where the condensation process cools down the vapor and converts it back into a liquid. Accordingly, the vaporizable working fluid is configured to undergo evaporation processes and condensation processes during operation of the package structure, thereby increasing a performance and reliability of the package structure.

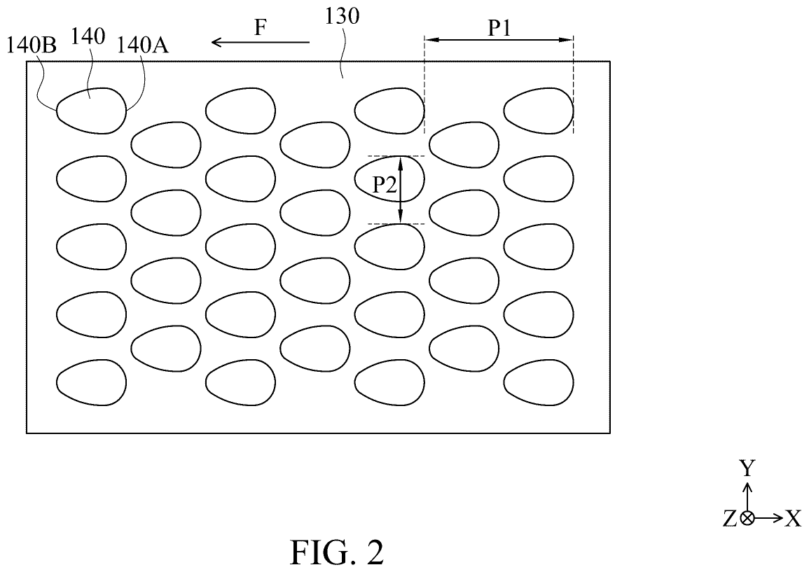

Next, as shown in FIG. 1D, the overall structure is flipped and a plurality of micro pillars 140 are formed on the second substrate 130. Accordingly, a supporting structure 112 is formed. In some embodiments, the formation of the micro pillars 140 may include performing a patterning process to the second substrate 130. For example, the patterning process includes: forming a masking layer (not shown) on the second substrate 130; performing an etching process (e.g., a dry etch process) on the second substrate 130 using the masking layer; and removing the masking layer from the second substrate 130. The detailed structure of the micro pillars 140 will be further discussed below in accompany with FIGS. 2 through 5. With the formation of the micro pillars 140, the surface area of the supporting structure 112 can be increased, thereby improving the thermal dissipation of the overall package structure. It should be noted that although the micro pillars 140 are formed after the first substrate 124 and the second substrate 130 are bonded together in the present embodiments, the micro pillars 140 may also be formed on the second substrate 130 before the vapor chambers 110 are formed by bonding the first substrate 124 and the second substrate 130.

In some embodiments, a distance between the vapor chambers 110 and the micro pillars 140 is ranged from about 130 μm to about 670 μm. For example, the distance can be measured from the top of vapor chambers 110 and the bottom of the micro pillars 140 in the normal direction (for example, the Z direction) of the second substrate 130. In this way, the second substrate 130 may have sufficient structural strength, and therefore the failure risk of the package structure can be reduced. In addition, the cooling liquid (for example, the cooling liquid 322 referring to FIG. 1G) may be separated from and prevented from flowing into the vapor chambers 110.

Then, as shown in FIG. 1E, a device structure 150 is provided or otherwise formed and the support structure 112 is bonded to the device structure 150. The device structure 150 includes a plurality of device dies 104 over a base structure 102. In various embodiments, the plurality of device dies 104 respectively include a plurality of semiconductor devices disposed on a semiconductor substrate and an interconnect structure electrically coupled to the plurality of semiconductor devices (not shown). The semiconductor devices may be or include one or more electronic device such as diodes, transistors, capacitors, resistors, or the like. Furthermore, the device dies 104 may be or include one or more IC dies or a stack of IC dies. In various embodiments, the device dies 104 may each be a system-on-chip (SoC), a system-on-integrated-circuit (SoIC), or the like. In some embodiments, the vapor chambers 110 overlie at least a portion of an individual device die 104. That is, the vapor chambers 110 at least partially overlap the device dies 104 in the normal direction (for example, the Z direction) of the support structure 112. Accordingly, the vapor chambers 110 may effectively dissipate the heat generated by the device dies 104.

In various embodiments, the base structure 102 is configured as an interposer that includes a lower substrate 208, a plurality of TSVs 210, a plurality of conductive interconnect structures 212, and a first plurality of conductive bond structures 214. In some embodiments, forming the device structure 150 includes: forming or otherwise providing the base structure 102 and the plurality of device dies 104; bonding the plurality of device dies 104 to the base structure 102; and forming a filler layer 106 over the base structure 102 and around the device dies 104. In various embodiments, bonding the support structure 112 to the device structure 150 includes: forming (e.g., by CVD, PVD, ALD, etc.) a dielectric bonding layer 108 on the plurality of device dies 104 and the filler layer 106; performing an alignment process (e.g., an optical alignment processes utilizing one or more alignment marks) to accurately align the support structure 112 over the plurality of device dies 104; and performing a bonding process (e.g., a fusion bonding process) to bond the support structure 112 to the device structure 150. In further embodiments, before forming the dielectric bonding layer 108 on the plurality of IC device dies 104, a planarization process (e.g., a CMP process) is performed on the plurality of device dies 104 and the filler layer 106 such that upper surfaces of the device dies 104 and the filler layer 106 are substantially flat and/or coplanar with one another.

In yet further embodiments, a plurality of conductive structures (not shown) may be formed or disposed in the dielectric bonding layer 108 before bonding the support structure 112 to the device structure 150. The conductive structures may, for example, be or include copper or some other suitable material. In various embodiments, the first plurality of conductive structures are aligned with the second plurality of conductive structures while bonding the support structure 112 to the device structure 150. In such embodiments, the support structure 112 meets the device structure 150 at a bonding interface that includes dielectric-to-dielectric bonds and conductor-to-conductor bonds.

In particular, the plurality of conductive interconnect structures 212 are disposed on an upper surface of the lower substrate 208. In some embodiments, the plurality of conductive interconnect structures 212 include conductive contacts, conductive vias, and/or conductive wires. The first plurality of conductive bond structures 214 are disposed in a dielectric structure 222. The first plurality of conductive bond structures 214 include bond vias, bond pads, other suitable bond structures, or any combination of the foregoing. Conductive features of the base structure 102 are configured to electrically couple the plurality of device dies 104 to one another and/or to another device (e.g., a PCB). The plurality of IC device dies 104 overlie the base structure 102. The device dies 104 comprise a second plurality of conductive bond structures 216 disposed in the dielectric structure 222. The second plurality of conductive bond structures 216 include bond vias, bond pads, other suitable bond structures, or any combination of the foregoing. One or more bonding interfaces are disposed between the base structure 102 and the device dies 104. The first plurality of conductive bond structures 214 meet the second plurality of conductive bond structures 216 at the one or more bonding interfaces. In various embodiments, the one or more bonding interfaces include conductor-to-conductor bonds and dielectric-to-dielectric bonds.

Then, as shown in FIG. 1F, a thinning process is performed on the lower substrate 208. In some embodiments, the thinning process reduces a thickness of the lower substrate 208 and exposes bottom surfaces of the TSVs 210. The thinning process may, for example, be or include a CMP process, a mechanical grinding process, or some other suitable process. In addition, a plurality of lower bond pads 204 and a plurality of solder bumps 202 are formed along a lower surface of the lower substrate 208. In some embodiments, forming the plurality of lower bonding pads 204 includes: forming (e.g., by CVD, PVD, ALD, etc.) a lower dielectric layer 206 along the lower surface of the lower substrate 208; etching the lower dielectric layer 206 to form a plurality of openings in the lower dielectric layer 206; and forming the plurality of lower bonding pads 204 in the plurality of openings.

Then, as shown in FIG. 1G, a liquid cooling component 300 is bonded over the support structure 112 (in particular, over the upper surface of the second substrate 130) via a sealant 330. As a result, the package structure 10 is formed. In some embodiments, the liquid cooling component 300 includes a manifold 310 to introduce cooling liquid 322 to dissipate the heat generated by the device dies 104. In some embodiments, the manifold 310 includes an inlet 311 and an outlet 312. The cooling liquid 322 flows into the inlet 311 (for example, along the inlet direction I) and performs a heat exchange with the second substrate 130 (in particular, the micro pillars 140). With the arrangement of the vapor chambers 110, the evaporation and condensation of the working fluid in the vapor chambers 110 would help to dissipate the heat upward to the liquid cooling component 300. As a result, the heat generated by the device dies 104 can be transferred to the cooling liquid 322 which flows in the flowing direction F. The heated cooling liquid 322 then travels to the outlet 312 and exits the liquid cooling component 300 (for example, along the outlet direction O), removing the heat generated by the device dies 104.

The liquid cooling component 300, the sealant 330, and the second substrate 130 may form at least one channel 320 over the vapor chambers 110. Accordingly, the sealant 330 may be located around the micro pillars 140. In other words, the sealant 330 is spaced apart from (i.e., do not overlap) the micro pillars 140 in the normal direction (for example, the Z direction) of the support structure 112. For example, the material of sealant 330 includes polymer or any other suitable waterproof material. In this way, the cooling liquid 322 may flow through the channels 320 in the flowing direction F without leakage. In some embodiments, the cooling liquid 322 may be cooled down after exiting the liquid cooling component 300, and refill into the liquid cooling component 300 for thermal dissipation. That is, the cooling liquid 322 may circulate through the micro pillars 140 in the package structure 10.

It should be noted that the package structure 10 in the present embodiment merely serves as an example, those skilled in the art should be able to realize that additional components may be added to the package structure 10 to achieve desired functions. Every possible configuration of the package structure 10 is included within the scope of the present disclosure.

FIG. 2 illustrates a plan view of the region P shown in FIG. 1G in accordance with some embodiments. As shown in FIG. 2, each of the micro pillars 140 includes a first flow guide surface 140A and a second flow guide surface 140B that is opposite to the first flow guide surface 140A. In some embodiments, the first flow guide surface 140A and the second flow guide surface 140B are substantially parallel to the normal direction (for example, the Z direction) of the second substrate 130. However, the present disclosure is not limited thereto. The cooling liquid 322 flows in the flowing direction F and contact the micro pillars 140. As set forth above, the micro pillars 140 increase the surface area of the supporting structure 112 (in particular, the second substrate 130), thereby improving the thermal dissipation of the overall package structure 10.

In some embodiments, the curvature of the first flow guide surface 140A is different from the curvature of the second flow guide surface 140B. For example, the curvature of the first flow guide surface 140A is less than the curvature of the second flow guide surface 140B. In other words, when viewed in the normal direction of the second substrate 130, the profile of the second guide surface 140B is sharper than the profile of the first guide surface 140B, while the profile of the first guide surface 140A is blunter than the profile of the second flow guide surface 140B. In particular, the cooling liquid 322 may be in contact with the first flow guide surface 140A first, and then pass through the second flow guide surface 140B. Through the above configuration, the micro pillars 140 can guide the cooling liquid 322 to generate turbulence as the cooling liquid 322 flows. As a result, the flow speed of the cooling liquid 322 may be increased, thereby improving the thermal dissipation of the overall package structure 10.

In some embodiments, the micro pillars 140 are arranged alternatively. That is, the adjacent columns of the micro pillars 140 are misaligned with each other. In this way, the cross-sectional area of the channels 320 varies along the flowing direction F of the cooling liquid 322, and therefore the flow speed of the cooling liquid 322 may be increased so as to improve the thermal dissipation of the package structure 10. However, the present disclosure is not limited thereto. In some embodiments, the pitch P1 between the adjacent micro pillars 140 in the horizontal direction (for example, the X direction) may be in a range from about 800 μm to about 1000 μm. In some embodiments, the pitch P2 between the adjacent micro pillars 140 in the vertical direction (for example, the Y direction) may be in a range from about 400 μm to about 600 μm. However, the present disclosure is not limited thereto. Such pitches P1 and P2 may provide sufficient space for flowing the cooling liquid 322, thereby ensuring the cooling liquid 322 in contact with the overall second substrate 130 (and the micro pillars 140). Otherwise, if any air gap exists between the cooling liquid 322 and the second substrate 130, the effective area for thermal dissipation would be decreased, and the thermal dissipation efficiency of the package structure 10 would be degraded. For example, the pitches P1 and P2 may be measured on the same point of the adjacent micro pillars 140.

In some embodiments, the profiles of the first flow guide surfaces 140A of the micro pillars 140 are substantially the same, and the profiles of the second flow guide surfaces 140B of the micro pillars 140 are substantially the same. However, the disclosure is not limited thereto. In other embodiments, the profiles of the first flow guide surfaces 140A and the second flow guide surface 140B of the micro pillars 140 can be adjusted based on the locations of the micro pillars 140. For example, the micro pillars 140 located over the hot spot may be specially shaped to be different from other for increasing the flow speed of the cooling liquid 322. It should be understood that all possible configurations of these micro pillars 140 are within the scope of the present disclosure.

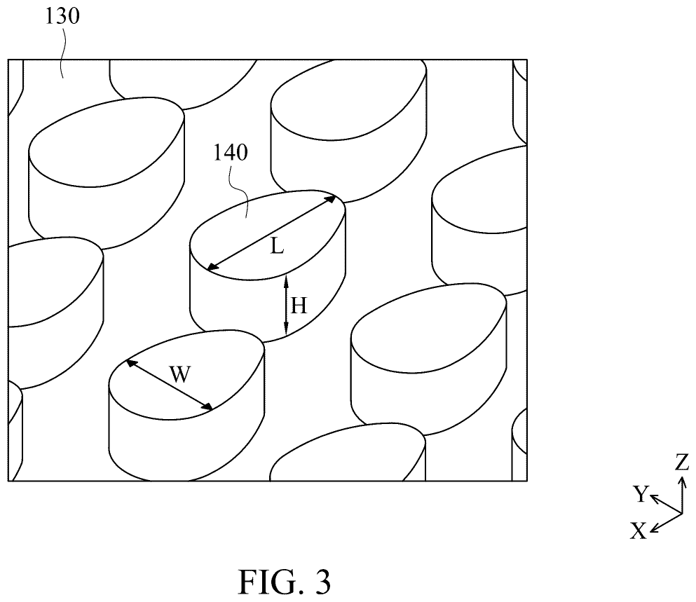

FIG. 3 illustrates a perspective view of the region P shown in FIG. 1G in accordance with some embodiments. As shown in FIG. 3, each of the micro pillars 140 may have a length L that is ranged from about 200 μm to about 500 μm, such as about 340 μm. It should be noted that the length L may be measured between two farthest points in the lengthwise direction (for example, the X direction) of the micro pillars 140. In some embodiments, each of the micro pillars 140 may have a width W that is ranged from about 100 μm to about 300 μm, such as about 220 μm. It should be noted that the width W may be measured between two farthest points in the widthwise direction (for example, the Y direction) of the micro pillars 140. In some embodiments, each of the micro pillars 140 may have a height H that is ranged from about 50 μm to about 300 μm, such as about 150 μm. It should be noted that the height H may be measured in the normal direction (for example, the Z direction) of the second substrate 130.

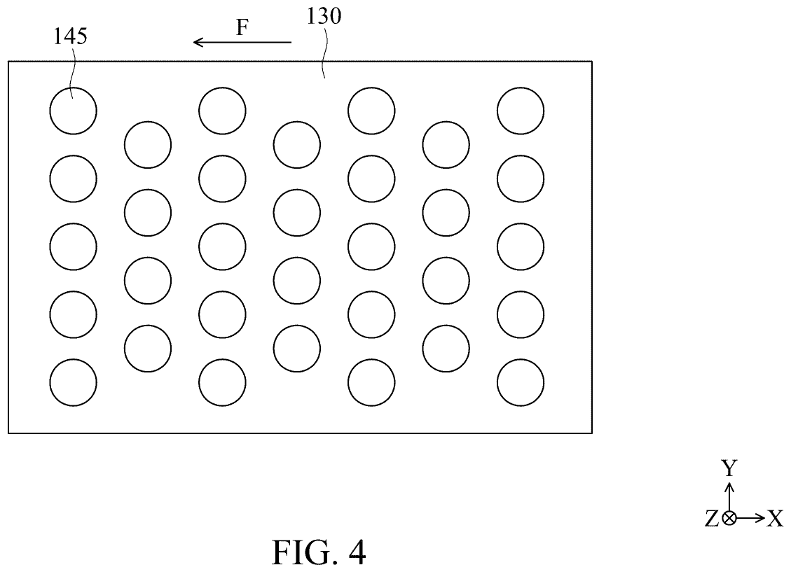

FIG. 4 illustrates a plan view of the region P shown in FIG. 1G in accordance with some embodiments. It should be noted that the package structure in the present embodiment may include portions or elements that are the same as or similar to those of the package structure shown in FIG. 2. For the sake of brevity, these portions or elements will be denoted by the same or similar numerals, and will not be discussed in detail as follows. As shown in FIG. 4, a plurality of circular micro pillars 145 replace the egg-shaped micro pillars 140 and are arranged over the second substrate 130. In this way, the formation of the micro pillars 145 can be simplified.

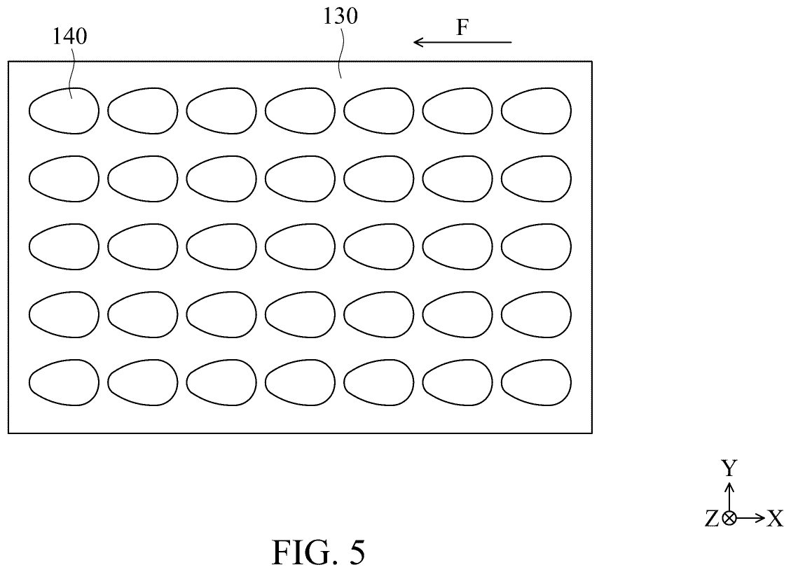

FIG. 5 illustrates a plan view of the region P shown in FIG. 1G in accordance with some embodiments. It should be noted that the package structure in the present embodiment may include portions or elements that are the same as or similar to those of the package structure shown in FIG. 2. For the sake of brevity, these portions or elements will be denoted by the same or similar numerals, and will not be discussed in detail as follows. As shown in FIG. 5, the adjacent columns of the micro pillars 140 are aligned with each other. As a result, the cooling liquid 322 may pass through the micro pillars 140 more smoothly. In some embodiments, the egg-shaped micro pillars 140 may be arranged in the same direction (for example, the X direction), but the present disclosure is not limited thereto. In some other embodiment, the egg-shaped micro pillars 140 may face different directions to generate desired flow of the cooling liquid 322.

Embodiments of package structures and methods for fabricating the same are provided. The package structure includes a plurality of vapor chamber sealed with vaporizable working fluid. The evaporation and condensation of the working fluid in the vapor chamber would help to dissipate the heat upward to the liquid cooling component. The package structure also includes a plurality of micro pillars over the supporting structure so as to increase the surface area of the supporting structure, thereby improving the thermal dissipation of the overall package structure. In particular, the cooling liquid flows into the channel formed by the liquid cooling component, the waterproof sealant, and the micro pillars to dissipate the heat generated by the device dies of the package structure. Accordingly, direct liquid cooling may be achieved and the thermal interface material (TIM) may be omitted. In some embodiments, the micro pillars can be formed as egg-shaped and includes flow guide surfaces with different curvatures. As a result, the micro pillars can guide the cooling liquid to generate turbulence as the cooling liquid flows. The flow speed of the cooling liquid may be increased, thereby improving the thermal dissipation of the overall package structure. In addition, the micro pillars are disposed with certain pitches to provide sufficient space for flowing the cooling liquid. The good fluidity of the cooling liquid also benefits the thermal dissipation of the package structure.

In some embodiments, a package structure is provided. The package structure includes a support structure comprising a first surface and a second surface opposite to the first surface. The package structure includes a device structure on the first surface of the support structure. The package structure includes a vapor chamber disposed in the support structure and over at least a portion of the device structure. The package structure includes a plurality of micro pillars formed on the second surface of the support structure and over the vapor chamber. The package structure also includes a liquid cooling component bonded over the second surface of the support structure and configured to circulate cooling liquid in contact with the micro pillars.

In some embodiments, a package structure is provided. The package structure includes a support structure comprising a first surface and a second surface opposite to the first surface. The package structure includes a device structure on the first surface of the support structure. The package structure includes a vapor chamber disposed in the support structure and over at least a portion of the device structure. The package structure also includes a liquid cooling component bonded over the second surface of the support structure and configured to introduce cooling liquid over the support structure. The cooling liquid is separated from vapor chamber.

In some embodiments, a method for fabricating a package structure is provided. The method includes forming a vapor chamber within a support structure. The method includes forming a plurality of micro pillars on the support structure. The micro pillars at least partially overlap the vapor chamber in a normal direction of the support structure. The method includes bonding the support structure to a plurality of device dies. The vapor chamber overlies at least a portion of an individual device die in the plurality of device dies. The method also includes bonding a liquid cooling component over the support structure. The liquid cooling component is configured to introduce cooling liquid in contact with the micro pillars.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a support structure comprising a first surface and a second surface opposite to the first surface;
a device structure on the first surface of the support structure;
a vapor chamber disposed in the support structure and over at least a portion of the device structure;
a plurality of micro pillars formed on the second surface of the support structure and over the vapor chamber; and
a liquid cooling component bonded over the second surface of the support structure and configured to circulate cooling liquid in contact with the micro pillars.

2. The package structure as claimed in claim 1, further comprising a sealant disposed between the liquid cooling component and the micro pillars.

3. The package structure as claimed in claim 1, wherein adjacent columns of the micro pillars are misaligned with each other in a plan view.

4. The package structure as claimed in claim 1, wherein each of the micro pillars includes a first flow guide surface and a second flow guide surface opposite to the first flow guide surface, and in a plan view, a curvature of the first flow guide surface is different from a curvature of the second flow guide surface.

5. The package structure as claimed in claim 4, wherein the cooling liquid flows from the first flow guide surface to the second flow guide surface, and the curvature of the first flow guide surface is less than the curvature of the second flow guide surface

6. The package structure as claimed in claim 1, wherein the micro pillars at least partially overlap the vapor chamber in a normal direction of the support structure.

7. The package structure as claimed in claim 1, wherein the liquid cooling component further comprises a manifold, and the cooling liquid flows from an inlet of the manifold to an outlet of the manifold through the micro pillars.

8. The package structure as claimed in claim 1, wherein the vapor chamber includes a first portion and a second portion connected to the first portion, a width of the first portion is less than a width of the second portion, and the second portion is closer to the liquid cooling component than the first portion.

9. The package structure as claimed in claim 8, wherein a thermal dispersion enhancement structure is formed in the second portion of the vapor chamber.

10. The package structure as claimed in claim 9, wherein the thermal dispersion enhancement structure comprises a dielectric layer, a seed layer on the dielectric layer, and a thermal dispersion enhancement layer on the seed layer.

11. A package structure, comprising:
a support structure comprising a first surface and a second surface opposite to the first surface;
a device structure on the first surface of the support structure;
a vapor chamber disposed in the support structure and over at least a portion of the device structure; and
a liquid cooling component bonded over the second surface of the support structure and configured to introduce cooling liquid over the support structure, wherein the cooling liquid is separated from vapor chamber.

12. The package structure as claimed in claim 11, wherein a plurality of micro pillars are formed on the second surface and protrude towards the liquid cooling component.

13. The package structure as claimed in claim 12, wherein in a plan view, the profile of the micro pillars is circular or egg-shaped.

14. The package structure as claimed in claim 12, wherein the liquid cooling component further comprises a manifold, the cooling liquid flows from an inlet of the manifold to an outlet of the manifold through the micro pillars.

15. A method for fabricating a package structure, comprising:
forming a vapor chamber within a support structure;
forming a plurality of micro pillars on the support structure, wherein the micro pillars at least partially overlap the vapor chamber in a normal direction of the support structure;
bonding the support structure to a plurality of device dies, wherein the vapor chamber overlies at least a portion of an individual device die in the plurality of device dies; and
bonding a liquid cooling component over the support structure, wherein the liquid cooling component is configured to introduce cooling liquid in contact with the micro pillars.

16. The method as claimed in claim 15, wherein forming the micro pillars on the support structure comprises:
forming a masking layer on the support structure;
performing an etching process on the support structure using the masking layer; and
removing the masking layer from support structure.

17. The method as claimed in claim 16, wherein the micro pillars are formed after the vapor chamber are formed within the support structure.

18. The method as claimed in claim 15, wherein forming the micro pillars on the support structure comprises:
forming a first flow guide surface and a second flow guide surface opposite to the first flow guide surface on each of the micro pillars, wherein in a plan view, a curvature of the first flow guide surface is different from a curvature of the second flow guide surface

19. The method as claimed in claim 15, wherein bonding the liquid cooling component over the support structure comprises:
disposing a sealant between the liquid cooling component and the support structure, wherein the sealant is located around the micro pillars.

20. The method as claimed in claim 15, wherein the cooling liquid flows from an inlet of a manifold in the liquid cooling component to an outlet of the manifold through the micro pillars.
